(19) United States
(12) Patent Application Publication
(10) Pub. No.: US 2025/0353293 A1
(43) Pub. Date: Nov. 20, 2025

(54) APPARATUS AND METHOD FOR CLEANING A STENCIL AND A METHOD FOR FORMING THE APPARATUS

(71) Applicant: STATS ChipPAC Pte. Ltd., Singapore (SG)

(72) Inventors: SeokBeom HEO, Incheon (KR); SeongKuk KIM, Gyeonggi-do (KR); SoYeong PARK, Incheon (KR); JuYub YIM, Ulsan (KR); HyunMi PARK, Incheon (KR)

(21) Appl. No.: 19/204,656

(22) Filed: May 12, 2025

(30) Foreign Application Priority Data
May 15, 2024 (CN) 202410604507.1

(51) Int. Cl. B41F 35/00; B08B 1/16; B08B 1/30; B08B 3/08; G03F 7/00; G03F 7/16; H05K 3/12

(52) U.S. Cl. CPC B41F 35/005; B08B 1/16; B08B 1/30; B08B 3/08; G03F 7/0002; G03F 7/168; H05K 3/1225

(57) ABSTRACT

An apparatus for cleaning a stencil, a method for forming the same and a method for cleaning a stencil are provided. The stencil comprises at least one cavity at a first surface of the stencil and a plurality of apertures extending within the stencil, and the apparatus comprises: a carrier; a supporting member attached on the carrier, and comprising a base portion and at least one cleaning portion protruding from the base portion, wherein each of the at least one cleaning portion is mateable with and receivable within one of the at least one cavity of the stencil; and a wiper detachably disposed on the supporting member, wherein the wiper is configured for being pressed against the stencil by the supporting member when the stencil is placed on the apparatus, to remove residuals within the apertures through direct contact between the wiper and the residuals.

### TECHNICAL FIELD

The present application generally relates to semiconductor technology, and more particularly, to an apparatus for cleaning a stencil, a method for forming the apparatus, and a method for cleaning a stencil.

### BACKGROUND OF THE INVENTION

A widely used method for fabricating electrical circuits is to apply solder paste to selected areas of a printed circuit board and then mount electronic components on the applied solder paste. A reflowing process of the solder paste is conducted to melt and reshape the solder paste, thereby bonding the electronic components to the printed circuit board and forming the electrical circuits.

During a solder paste printing process, the solder paste is applied through a stencil with apertures which are positioned corresponding to the areas where the electronic components are to be connected with the printed circuit board. The solder paste is applied to a top surface of the stencil and a portion of the solder paste flows through the stencil apertures and adheres to the printed circuit board. In some cases, cavities are formed within the stencil depending on a layout of the electrical circuit to be formed.

In order to form reliable solder bumps with the stencil, it is critical that residuals remained within the apertures of the stencil should be sufficiently removed after a solder paste printing process such that the residuals would not adversely affect solder bumps formed in a subsequent solder paste printing process using the same stencil.

Therefore, a need exists for an apparatus for cleaning a stencil with improved cleaning effect.

### SUMMARY OF THE INVENTION

An objective of the present application is to provide an apparatus for cleaning a stencil with improved cleaning effect.

According to an aspect of the present application, an apparatus for cleaning a stencil is provided. The stencil comprises at least one cavity at a first surface of the stencil, and a plurality of apertures extending within the stencil between the at least one cavity and a second surface of the stencil which is opposite to the first surface, and the apparatus comprises: a carrier; a supporting member attached on the carrier, and comprising a base portion and at least one cleaning portion protruding from the base portion, wherein each of the at least one cleaning portion is mateable with and receivable within one of the at least one cavity of the stencil; and a wiper detachably disposed on the supporting member, wherein the wiper is configured for being pressed against the stencil by the supporting member when the stencil is placed on the apparatus, to remove residuals within the apertures through direct contact between the wiper and the residuals.

According to another aspect of the present application, a method for making an apparatus for cleaning a stencil is provided. The stencil comprises at least one cavity at a first surface of the stencil and a plurality of apertures extending within the stencil between the at least one cavity and a second surface of the stencil which is opposite to the first surface, and the method comprises: providing a carrier; attaching a supporting material on the carrier; patterning the supporting material corresponding to the stencil to form a supporting member comprising a base portion and at least one cleaning portion protruding from the base portion, wherein each of the at least one cleaning portion is mateable with and receivable within one of the at least one cavity of the stencil; and attaching a wiper on the supporting member.

According to another aspect of the present application, a method for cleaning a stencil is provided. The stencil comprises at least one cavity at a first surface of the stencil, and a plurality of apertures extending within the stencil between the at least one cavity and a second surface of the stencil which is opposite to the first surface, and the method comprises: providing a stencil cleaning apparatus, wherein the stencil cleaning apparatus comprises a carrier, a supporting member attached on the carrier and comprising a base portion and at least one cleaning portion protruding from the base portion, and a wiper detachably disposed on the supporting member; mounting the stencil on the stencil cleaning apparatus to accommodate each of the at least one cleaning portion within one of the at least one cavity of the stencil and press the wiper against the stencil; and moving the stencil cleaning apparatus with respect to the stencil to remove residuals within the apertures of the stencil through direct contact between the wiper and the residuals.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates a perspective view of a stencil from a top side of the stencil and an apparatus for cleaning the stencil according to a first embodiment of the present application.

FIG. 1B illustrates a perspective view of the stencil from a bottom side of the stencil shown in FIG. 1A.

FIG. 1C illustrates a cross-sectional view of the stencil along line AA′ shown in FIG. 1A.

FIG. 1D illustrates a cross-sectional view of the apparatus for cleaning the stencil along line BB′ shown in FIG. 1A.

FIGS. 2A to 2D illustrate various steps of a method for cleaning a stencil according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, during a solder paste printing process, solder paste is applied through a stencil with apertures which are positioned corresponding to areas where electronic components are to be connected with a printed circuit board. The solder paste is applied onto a top surface of the stencil, and a portion of the solder paste flows through the stencil apertures and adheres to the printed circuit board. In order to form reliable circuits with the stencil, it is critical that residuals remained within the apertures of the stencil should be sufficiently removed after a solder paste printing process such that the residuals would not adversely affect subsequent solder paste printing processes using the same stencil.

In some cases, cavities may be formed within a stencil, with apertures extending within the stencil between the cavities and a top surface of the stencil. However, it is difficult to remove solder paste residuals from the cavities and especially the apertures within such cavities using conventional stencil cleaning tools. To address this issue, a new apparatus for cleaning a stencil is provided. The apparatus includes a supporting member having at least one cleaning portion protruding from a base portion, each of which mates with and can be received within one of the cavities of the stencil. A wiper is further disposed on the supporting member, which may be used to remove residuals within the apertures through direct contact between the wiper and the residuals. As such, the new apparatus may allow for an improved cleaning effect of stencils with uneven surfaces.

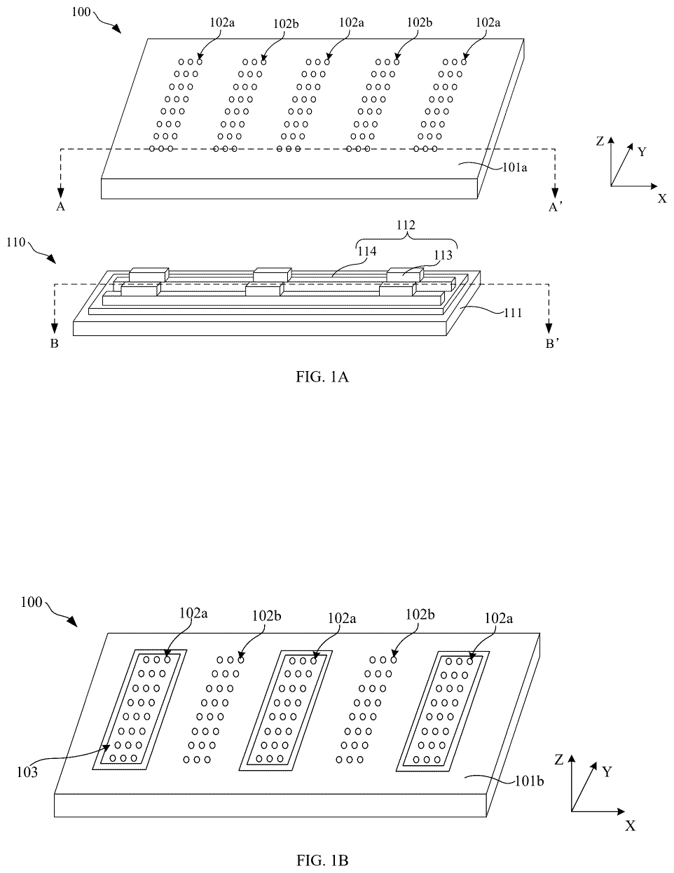

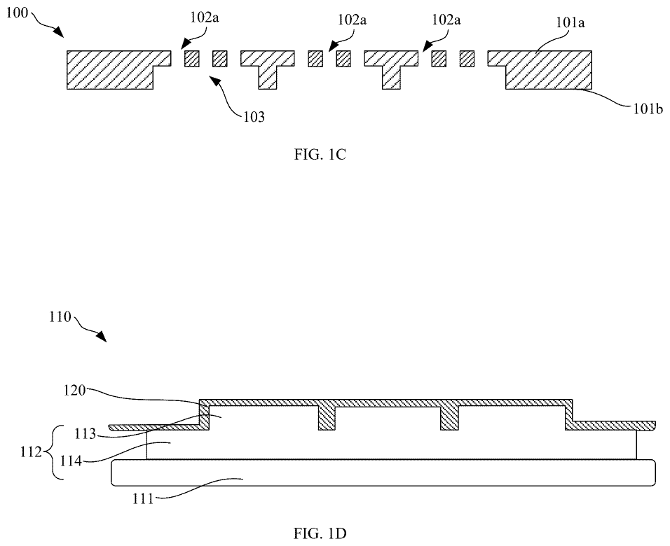

FIGS. 1A to 1D illustrate a stencil and an apparatus for cleaning the stencil according to a first embodiment of the present application. To be more specific, FIG. 1A illustrates a perspective view of a stencil from a top side of the stencil and the apparatus for cleaning the stencil, FIG. 1B illustrates a perspective view of the stencil from a bottom side of the stencil, FIG. 1C illustrates a cross-sectional view of the stencil along line AA′ shown in FIG. 1A, and FIG. 1D illustrates a cross-sectional view of the apparatus for cleaning the stencil along line BB′ shown in FIG. 1A.

As shown in FIG. 1A, a stencil 100 having a plurality of apertures 102a is provided. The stencil 100 is used to implement a solder paste printing process where solder paste is applied through the apertures 102a of the stencil 100 to form electrical connections between a printed circuit board and at least one electronic component mounted thereon. After a solder paste printing process, a thorough cleaning process should be implemented to remove solder paste residuals within the apertures 102a of the stencil 100. As shown in FIGS. 1B and 1C, the stencil 100 further includes at least one cavity 103 at a first surface of the stencil 100, for example, a bottom surface 101b of the stencil 100. The at least one cavity 103 extends within the stencil 100 from an interior of the stencil 100 to the bottom surface 101b of the stencil 100.

The apertures 102a are arranged at a second surface of the stencil 100 which is opposite to the first surface, for example, a top surface 101a of the stencil 100. The apertures 102a extend within the stencil 100 from the second surface 101a to the at least one cavity 103, and are thus fluidly connected with the at least one cavity 103. The connected apertures 102a and cavities 103 form respective channels that extend through the stencil 100 and allow for passages of the solder paste through the stencil 100. In some embodiments, each of the at least one cavity 103 has a rectangular layout, and each of the at least one cavity 103 is connected with a group of apertures 102a allocated in parallel lines which are arranged in a lengthwise direction Y of the stencil 100. In some other embodiments, the cavity 103 may have a different layout, such as a circle, a hexagon or an octagon. In some embodiments, the stencil 100 further includes additional apertures 102b extending through the stencil 100 between its top surface 101a and bottom surface 101b without being connected with a cavity. The additional apertures 102b may also be allocated into groups which are similar to the groups of the apertures 102a, such that each group of the additional apertures 102b are arranged adjacently to one group of the apertures 102a. However, it can be appreciated that apertures 102a and 102b can be arranged differently depending on the desired layout of solder bumps to be formed on the printed circuit board or other similar substrates. In some embodiments, the stencil 100 may be made of stainless steel, nickel, brass or other suitable material. The stencil 100 can be preformed according to the solder paste printing requirement.

As shown in FIGS. 1A and 1D, the apparatus 110 is provided for cleaning the stencil 100. After the solder paste printing process, the apparatus 110 is used to remove solder paste residuals within the apertures 102a and 102b of the stencil 100, or to clean other regions of the stencil 100. The apparatus 110 includes a carrier 111 with an optional intermediate layer on a top surface of the carrier 111, which serves as a platform for placing cleaning components. A supporting member 112 is attached on the carrier 111 via the intermediate layer. The supporting member 112 includes a base portion 114 and at least one cleaning portion 113 protruding from the base portion 114. In the embodiment, each of the at least one cleaning portion 113 mates with one of the at least one cavity 103 of the stencil 100 such that the at least one cleaning portion 113 is receivable within one of the at least one cavity 103. In other words, each of the at least one cleaning portion 113 has a similar size (e.g., substantially the same or slightly smaller) in a widthwise direction X and an altitudinal direction Z of the stencil 100 as each of the at least one cavity 103. Additionally, an external surface of the at least one cleaning portion 113 also mates with an internal surface of the at least one cavity 103 in profile or contour, which allows direct or indirect contact between the at least one cleaning portion 113 and the stencil 100 within the at least one cavity 103 when the stencil 100 is placed on the apparatus 110. Such contact between the cleaning portion 113 and the stencil 100 especially within the cavities 103 can generate frictions that helps removing the residuals from the stencil 100.

As shown in FIG. 1D, the apparatus 110 further includes a wiper 120 detachably disposed on the supporting member 112. When the stencil 100 is placed on the apparatus 110, the wiper 120 is disposed between the stencil 100 and the supporting member 112, and thus it can be pressed against the stencil 100 by the supporting member 112 at all regions of the at least one cleaning portion 113 and the base portion 114. As such, the wiper 120 can be in direct contact with the residuals remained on the stencil 100 to remove them efficiently. In some embodiments, the wiper 120 includes polypropylene or cotton. It can be appreciated that the wiper 120 includes other materials suitable for cleaning, such as a fabric material.

Still referring to FIGS. 1A to 1D, the at least one cavity 103 and the at least one cleaning portion 113 are both arranged in the widthwise direction X of the stencil 100. Each of the at least one cleaning portion 113 has a smaller size in the lengthwise direction Y of the stencil 100 than one of the at least one cavity 103. In some embodiments, when the apparatus 110 is cleaning the stencil 100, the carrier 111 is movable relative to the stencil 100 in the lengthwise direction Y of the stencil 100. As such, the supporting member 112 attached on the carrier 111 may be moved accompanying the movement of the carrier 111. In some embodiments, the carrier 111 is shaped as a roller, and a driver may be coupled to the carrier 111 to roll the carrier 111 cyclically with respect to the stencil 100 when the apparatus 110 is cleaning the stencil 100. In some other embodiments, the carrier 111 may be shaped as a plate or other similar planar structures, and can be placed on the stencil 100 and moved along the stencil 100 cyclically when the apparatus 110 is cleaning the stencil 100.

To be more specific, each of the at least one cleaning portion 113 moves within one of the at least one cavity 103 in the lengthwise direction Y of the stencil 100. During this process, the wiper 120 disposed on the supporting member 112 may scrub the bottom surface 101b of the stencil 100 and the internal surface of the at least one cavity 103 with the movement of the supporting member 112. For the stencil includes both apertures 102a and additional apertures 102b, the apparatus 110 may remove residuals within the apertures 102a and the additional apertures 102b simultaneously. Moreover, as shown in FIGS. 1A and 1D, the base portion 114 may be a rectangular bar, which has a similar size in the widthwise direction X of the stencil 100 compared with a widthwise size of the stencil 100. As such, the wiper 120 disposed on the supporting member 112 may be in direct contact with almost all regions of the bottom surface 101b of the stencil 100 and the internal surface of the at least one cavity 103 when the supporting member 112 moves relative to the stencil 100 in the lengthwise direction Y of the stencil 100. Therefore, the residuals within the apertures 102a and the additional apertures 102b may be removed thoroughly. It can also be appreciated that the supporting member 112 may be configured to allow direct contact between the wiper 120 and the residuals within the apertures 102a but allow a minor gap between the wiper 120 and the surface of the stencil 100. In some embodiments, there may be more than one supporting member 112 attached separately on the carrier 111 to further improve the cleaning efficiency. The supporting members 112 may be integrated on the intermediate layer optionally disposed on the carrier 111.

In some other embodiments, the supporting member 112 may further include at least one protrusion on an edge of the supporting member 112. Accordingly, the stencil 100 may include at least one slot configured for receiving the at least one protrusion, such that each of the at least one protrusion can move within one of the at least one slot when the supporting member 112 moves relative to the stencil 100. In this way, an unexpected displacement between the stencil 100 and the supporting member 112 may be avoided, which may achieve a uniform and thorough cleaning effect. It can also be appreciated that the at least one protrusion may be formed on a marginal region of the carrier 111 to be received within the at least one slot.

It should be noted that a portion of the stencil 100 including the additional apertures 102b in FIGS. 1A and 1B may be omitted in FIG. 1C for simplicity, and a portion of the apparatus 110 for cleaning the stencil 100 that corresponds to the portion of the stencil 100 including the additional apertures 102b is also omitted in FIG. 1D for simplicity. In other words, FIG. 1C exemplarily illustrates a cross-sectional view of a portion of the stencil 100 including apertures 102a shown in FIGS. 1A and 1B, and a portion of the apparatus 110 for cleaning the stencil 100 that corresponds to the portion of the stencil 100 including the apertures 102a is illustrated in FIG. 1D.

In another aspect of the present application, a method for making an apparatus for cleaning a stencil is provided. The stencil and the apparatus may be similar as the stencil 100 and the apparatus 110 illustrated in FIGS. 1A to 1D.

To be more specific, a carrier is provided, which serves as a platform for placing cleaning components. Next, a supporting material is attached on the carrier. In some embodiments, the supporting material may include silicon rubber or other materials which can be etched to change its shape. A supporting stencil having openings passing therethrough is placed on the supporting material. The openings of the supporting stencil are formed in layout and profile corresponding to the at least one cavity of the stencil, in order to pattern the supporting material and form at least one cleaning portion, for example, the cleaning portions 113 shown in FIGS. 1A and 1D. More specifically, the openings are aligned with a portion of the stencil other than the at least one cavity. A top surface of the supporting material may be covered by a portion of the supporting stencil, which is aligned with the at least one cavity. Next, a portion of the supporting material exposed from the openings of the supporting stencil may be etched by a dry etching process or a wet etching process. The other portion of the supporting material may be prevented from the etching process due to a coverage of the supporting stencil, thereby forming a base portion and at least one cleaning portion protruding from the base portion, for example, the base portion 114 and the cleaning portion 113 shown in FIGS. 1A and 1D. In this way, the supporting member is formed. In some other embodiments, a mask layer with openings passing therethrough may be formed on a top surface of the supporting material instead of using the supporting stencil to form the at least one cleaning portion. The mask layer may include a photoresist material or other anti-corrosion materials to pattern the supporting material during an etching process.

In some other embodiments, the supporting material includes a flexible material which is deformable when applied with an external force. Additionally, in some embodiments, the flexible material can be cured by a heating process after the deformation, so as to have the supporting material solidified with the desired shape. To be more specific, the stencil is placed on the flexible material, which may be pressed against the carrier with the stencil. During the pressing step, a portion of the flexible material may be extruded into the at least one cavity of the stencil, thereby forming the at least one cleaning portion corresponding to the at least one cavity of the stencil. As such, the at least one cleaning portion may be constructed to mate with and be receivable within one of the at least one cavity of the stencil in a convenient way with a low cost. Next, the supporting material is cured by a heating process to form the supporting member. In some embodiments, the flexible material may include silicone, rubber and other deformable materials. In some embodiments, the supporting material may shrink after being cured, thereby providing a space and thickness to dispose a wiper thereon. In some embodiments, the flexible material includes a thermoset material. Before placing the stencil on the thermoset material, the thermoset material may first be heated to a temperature to increase its flexibility. In some other embodiments, the flexible material includes a thermoplastic material, which can be deformed again through a heating process after being cured, thereby allowing for a cyclic utilization of the supporting material used in apparatuses for cleaning different stencils.

Next, a wiper is attached on the supporting member, for example, through adhesive. In this way, the apparatus can be formed.

More details of the stencil and the apparatus for cleaning the stencil may be similar to the stencil 100 and the apparatus 110 illustrated in FIGS. 1A to 1D, which will not be elaborated in detail here for simplicity.

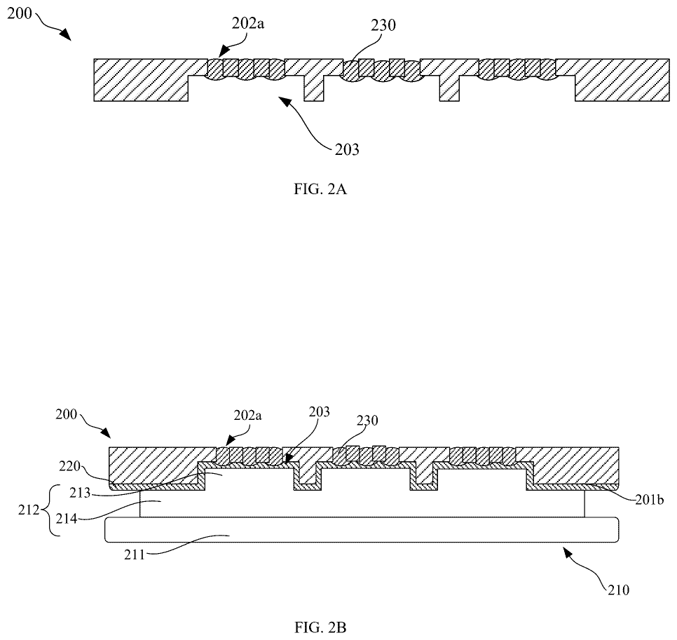

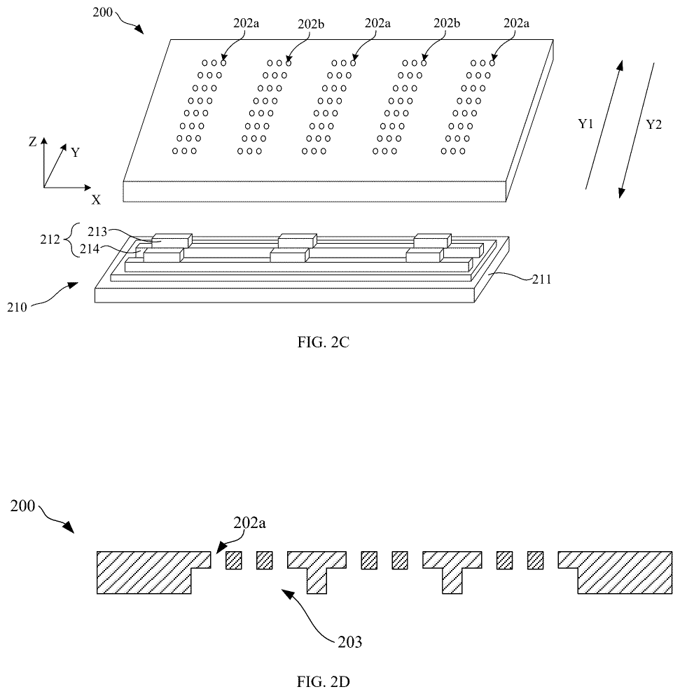

FIGS. 2A to 2D illustrate various steps of a method for cleaning a stencil according to a second embodiment of the present application.

As shown in FIG. 2A, a stencil 200 that has been used in a solder paste printing process is provided. During the solder paste printing process, solder paste residuals 230 may be remained within apertures 202a of the stencil 200, which need to be removed from the stencil 200. The stencil 200 having at least one cavity 203 may be similar as the stencil 100 illustrated in FIGS. 1A to 1C, which will not be elaborated in detail here for simplicity.

As shown in FIG. 2B, a stencil cleaning apparatus 210 is provided. The stencil cleaning apparatus 210 includes a carrier 211, a supporting member 212 attached on the carrier 211, and a wiper 220 detachably disposed on the supporting member 212. The supporting member 212 includes a base portion 214 and at least one cleaning portion 213 protruding from the base portion 214. The stencil cleaning apparatus 210 may be similar as the apparatus 110 for cleaning the stencil 100 illustrated in FIGS. 1A and 1D, which will not be elaborated in detail here for simplicity.

Next, the stencil 200 is mounted on the stencil cleaning apparatus 210 to accommodate each of the at least one cleaning portion 213 within one of the at least one cavity 203 of the stencil 200. In the embodiment, each of the at least one cleaning portion 213 has a smaller size in a lengthwise direction of the stencil 200 than one of the at least one cavity 203. The at least one cleaning portion 213 may be placed at a front end of the cavity 203.

Next, the wiper 220 is pressed against the stencil 200 to allow for direct contact between the wiper 220 and the residuals 230. In some embodiments, the wiper 220 is in direct contact with an internal surface of the at least one cavity 203 and a bottom surface 201b of the stencil 200, as shown in FIG. 2B, for example. In some other embodiments, the wiper 220 is in direct contact with residuals 230 within the apertures 202a while a minor gap may exist between the wiper 220 and the surface of the stencil 200. Next, a cleaning agent may be applied between the wiper 220 and the stencil 200 to improve a cleaning efficiency. In some embodiments, the cleaning agent includes isopropyl alcohol.

As shown in FIG. 2C, the carrier 211 may be moved relative to the stencil 200 in a lengthwise direction Y of the stencil 200, for example, by a driver coupled to the carrier 211. The supporting member 212 attached on the carrier 211 may be moved with respect to the stencil 200 along with the movement of the carrier 211. To be more specific, each of the at least one cleaning portion 213 moves within one of the at least one cavity 203 in a lengthwise direction Y of the stencil 200 from a front end of the cavity 203 to a rear end of the cavity 203. During this process, the wiper 220 disposed on the supporting member 212 may scrub the surface of the stencil 200 with the movement of the supporting member 212. For example, a portion of the wiper 220 disposed on the cleaning portion 213 may be used to scrub the internal surface of the at least one cavity 203 with a direct contact between the wiper 220 and the residuals 230 within the apertures 202a above the cavity 203. Additionally, a portion of the wiper 220 disposed on a top surface of the base portion 214 may be used to scrub the bottom surface of the stencil 200 where the at least one cavity 203 does not extend, for example, the bottom surface of a portion of the stencil 200 where additional apertures 202b are formed. As such, the residuals 230 within both of the apertures 202a and the additional apertures 202b may be removed simultaneously despite of a height difference between the apertures 202a and the additional apertures 202b, thereby increasing a cleaning efficiency and effectiveness.

In some embodiments, a cleaning process of the stencil 200 may include multiple cleaning cycles of movement of the stencil cleaning apparatus 210 with respect to the stencil 200. During a first cleaning cycle, the carrier 211 moves such that each of the at least one cleaning portion 213 moves within one of the at least one cavity 203 from a front end of the cavity 203 to a rear end of the cavity 203, which is illustrated as direction Y1 in FIG. 2C. Once the at least one cleaning portion 213 arrives at the rear end of the at least one cavity 203, the carrier 211 may be moved in an opposite direction such that each of the at least one cleaning portion 213 may be moved from the rear end of the cavity 203 to the front end of the cavity 203 (as illustrated as direction Y2 in FIG. 2C), which is referred to as a second cleaning cycle. In some embodiments, the cleaning process may include more than two cleaning cycles, and every two successive cleaning cycles have opposite moving directions of the carrier 211, such as Y1 and Y2. In other words, the stencil cleaning apparatus 210 moves with respect to the stencil 200 back and forth between a front side and a rear side of the stencil cyclically. As such, the residuals 230 within the apertures 202a and additional apertures 202b may be removed more thoroughly due to the back-and-forth scrubbing by the wiper 220 towards the surface of the stencil 200. In some embodiments, the stencil 200 may include multiple modules, and each of the cleaning cycles may be used to clean a different module. The carrier 211 may also be moved by a driver in a widthwise direction X or other arbitrary directions to move the supporting member 212 to mate with other modules of the stencil 200 during different cleaning cycles. In some embodiments, the carrier 211 is shaped as a roller, and a driver may be coupled to the carrier 211 and configured to roll the carrier 211 cyclically with respect to the stencil 200 when the stencil cleaning apparatus 210 is cleaning the stencil 200.

Next, the stencil cleaning apparatus 210 is removed from the stencil 200. As shown in FIG. 2D, the residuals 230 within the apertures 202a and the additional apertures 202b of the stencil 200 may be thoroughly removed. Finally, a washing process may be applied to the stencil 200 to remove the remaining cleaning agent from the stencil 200, thereby completing a cleaning process of the stencil 200.

While the exemplary apparatus and method for cleaning a stencil of the present application are described in conjunction with corresponding figures, it will be understood by those skilled in the art that modifications and adaptations to the apparatus and the method for cleaning a stencil may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An apparatus for cleaning a stencil, wherein the stencil comprises at least one cavity at a first surface of the stencil, and a plurality of apertures extending within the stencil between the at least one cavity and a second surface of the stencil which is opposite to the first surface, and wherein the apparatus comprises:
a carrier;
a supporting member attached on the carrier, and comprising a base portion and at least one cleaning portion protruding from the base portion, wherein each of the at least one cleaning portion is mateable with and receivable within one of the at least one cavity of the stencil; and
a wiper detachably disposed on the supporting member, wherein the wiper is configured for being pressed against the stencil by the supporting member when the stencil is placed on the apparatus, to remove residuals within the apertures through direct contact between the wiper and the residuals.

2. The apparatus of claim 1, wherein the at least one cavity is arranged in a widthwise direction of the stencil, and each of the at least one cleaning portion has a smaller size in a lengthwise direction of the stencil than a respective one of the at least one cavity, the carrier is movable relative to the stencil in a lengthwise direction of the stencil such that each of the at least one cleaning portion moves within one of the at least one cavity when the apparatus is cleaning the stencil.

3. The apparatus of claim 1, wherein the supporting member comprises silicon rubber.

4. The apparatus of claim 1, wherein the supporting member comprises a flexible material cured by a heating process.

5. The apparatus of claim 4, wherein the supporting member comprises a thermoset material or a thermoplastic material.

6. The apparatus of claim 1, wherein the wiper comprises polypropylene or cotton.

7. The apparatus of claim 1, wherein the carrier is shaped as a roller.

8. The apparatus of claim 7, further comprising:
a driver coupled to the carrier and configured to roll the carrier cyclically with respect to the stencil when the apparatus is cleaning the stencil.

9. A method for making an apparatus for cleaning a stencil, wherein the stencil comprises at least one cavity at a first surface of the stencil and a plurality of apertures extending within the stencil between the at least one cavity and a second surface of the stencil which is opposite to the first surface, and wherein the method comprises:
providing a carrier;
attaching a supporting material on the carrier;
patterning the supporting material corresponding to the stencil to form a supporting member comprising a base portion and at least one cleaning portion protruding from the base portion, wherein each of the at least one cleaning portion is mateable with and receivable within one of the at least one cavity of the stencil; and
attaching a wiper on the supporting member.

10. The method of claim 9, wherein patterning the supporting material comprises:
etching at least a portion of the supporting material corresponding to the at least one cavity of the stencil to form the at least one cleaning portion.

11. The method of claim 9, wherein the supporting material comprises a flexible material that can be cured by a heating process, and wherein patterning the supporting material comprises:
placing the stencil on the supporting material;
pressing the supporting material against the carrier with the stencil to form the at least one cleaning portion corresponding to the at least one cavity of the stencil; and
curing the supporting material by a heating process to form the supporting member.

12. A method for cleaning a stencil, wherein the stencil comprises at least one cavity at a first surface of the stencil, and a plurality of apertures extending within the stencil between the at least one cavity and a second surface of the stencil which is opposite to the first surface, and wherein the method comprises:
providing a stencil cleaning apparatus, wherein the stencil cleaning apparatus comprises a carrier, a supporting member attached on the carrier and comprising a base portion and at least one cleaning portion protruding from the base portion, and a wiper detachably disposed on the supporting member;
mounting the stencil on the stencil cleaning apparatus to accommodate each of the at least one cleaning portion within one of the at least one cavity of the stencil and press the wiper against the stencil; and
moving the stencil cleaning apparatus with respect to the stencil to remove residuals within the apertures of the stencil through direct contact between the wiper and the residuals.

13. The method of claim 12, wherein the at least one cavity is arranged in a widthwise direction of the stencil, and each of the at least one cleaning portion has a smaller size in a lengthwise direction of the stencil than a respective one of the at least one cavity, and moving the stencil cleaning apparatus with respect to the stencil comprises: moving the carrier relative to the stencil in a lengthwise direction of the stencil such that each of the at least one cleaning portion moves within one of the at least one cavity.

14. The method of claim 13, wherein moving the stencil cleaning apparatus with respect to the stencil comprises multiple cleaning cycles, and each of the cleaning cycles comprising:
moving the stencil cleaning apparatus with respect to the stencil cyclically and back and forth between a front side and a rear side of the stencil.

15. The method of claim 12, wherein before moving the stencil cleaning apparatus with respect to the stencil, the method further comprises: applying a cleaning agent between the wiper and the stencil.

16. The method of claim 15, wherein the cleaning agent comprises isopropyl alcohol.
